(19) United States
(12) Patent Application Publication
(10) Pub. No.: US 2025/0356942 A1
(43) Pub. Date: Nov. 20, 2025

(54) PARTIAL MEMORY ACCESS OF ERROR PROTECTED MEMORY

(71) Applicant: Micron Technology, Inc., Boise, ID (US)

(72) Inventor: Leon Zlotnik, Camino, CA (US)

(21) Appl. No.: 19/174,751

(22) Filed: Apr. 9, 2025

Related U.S. Application Data
(60) Provisional application No. 63/633,581, filed on Apr. 12, 2024.

(51) Int. Cl. G11C 29/52; G11C 7/10

(52) U.S. Cl. CPC G11C 29/52; G11C 7/1075; G11C 7/1093; G11C 7/1096

(57) ABSTRACT

Described are methods, memory devices, and machine-readable mediums that reduce a partial write latency for error correcting memory systems. The disclosed techniques may utilize either two port, or pseudo two-port memory and an ECC cache to minimize partial-write latency to a single clock cycle. In some examples, on a first clock cycle, the CPU puts partial write data on the bus along with the write address (but does not include an updated ECC). At the same time, the memory device outputs the previous value stored at that address and the previous ECC. At the next clock cycle, the new (updated) ECC is calculated and stored in an ECC cache. During a same clock cycle as the new ECC is being calculated and stored, the previous data integrity (i.e. no ECC errors on the existing data) can be checked and another write, either partial or full, can occur.

Micron Confidential

### PRIORITY APPLICATION

This application claims the benefit of priority to U.S. Provisional Application Ser. No. 63/633,581, filed Apr. 12, 2024, which is incorporated herein by reference in its entirety.

### TECHNICAL FIELD

Embodiments pertain to memory devices. Some embodiments relate to error-correcting memory systems that include error detection and correction. Some additional embodiments relate to error-correcting memory systems that provide enhanced efficiency for writing of a partial word in the memory where the error detection and/or correction code is applied to a full word.

### BACKGROUND

Memory devices for computers or other electronic devices may be categorized as volatile and non-volatile memory. Volatile memory requires power to maintain its data, and includes random-access memory (RAM), dynamic random-access memory (DRAM), Static Random Access Memory (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, phase-change memory, storage class memory, resistive random-access memory (RRAM), and magnetoresistive random-access memory (MRAM), among others.

Memory devices may interface with a host, such as a processor or another computing device, to store essential data, commands, and instructions. The connection between the host and memory devices can be established via a local bus or interconnect (e.g., the system bus), allowing the memory devices to function within the host's system such as within a traditional computing device. Alternatively, memory devices can be configured within a distributed memory system, which involves a network of interconnected hosts and memory devices which may span across multiple locations. This configuration enables the creation of expansive systems that harness the collective resources of numerous hosts and memory devices.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates an example computing environment including a memory system, in accordance with some examples of the present disclosure.

FIG. 2 illustrates a partial write according to some examples of the present disclosure.

FIG. 3 illustrates an improved partial write according to some examples of the present disclosure.

FIG. 4A illustrates a system for performing memory operations using a pseudo two-port memory with an ECC cache according to some examples of the present disclosure.

FIG. 4B illustrates a system for performing memory operations using a two-port memory with an ECC cache according to some examples of the present disclosure.

FIG. 5 illustrates a logical diagram of an ECC cache system designed to optimize memory operations by efficiently managing error-correcting codes during partial write operations according to some examples of the present disclosure.

FIG. 6 illustrates a flowchart depicting an exemplary method for performing a partial write to a code-protected memory region of a memory device, according to some examples of the present disclosure.

FIG. 7 is a block diagram illustrating an example of a machine upon which one or more embodiments may be implemented.

### DETAILED DESCRIPTION

An error-detecting memory system is a memory system that employs error coding techniques to enhance data integrity by detecting errors that may occur during data storage and retrieval processes. Error-correcting memory systems extend this concept to not only allow the system to detect errors but also to correct certain errors. Error detection and/or correction can be achieved by adding redundant data, or “code,” to the information being stored, which can be used later to verify and repair corrupted data.

Error-correction code (ECC) memory is one type of error-correcting memory system. ECC involves algorithms that extend the standard data storage code with additional bits, known as check bits, which are calculated from the data bits using specific ECC algorithms. In some examples, ECC memory systems use Hamming codes to generate the check bits. The ECC algorithms are designed to identify and correct common types of errors, such as single-bit errors, and in some cases, to detect (but not necessarily correct) more complex multi-bit errors. For example, ECC memory may use 10 ECC bits for every 256 bits of data to correct single-bit errors and detect double-bit errors. Other types of error-correcting memory systems include Forward Error Correction (FEC), low density codes, high density codes, parity codes, cyclic redundancy checks, and the like.

Error-correcting memory systems techniques are useful in systems where data accuracy is important, such as in critical computing environments, communication systems, and storage devices. While error-correcting memory systems, including ECC, typically introduce additional computational and storage overhead, leading to higher costs and potentially slower access times, the trade-off for enhanced reliability and reduced data corruption risk is often considered worthwhile, especially in applications where the cost of an error could be substantial.

In ECC memory systems, error correction code bits are calculated using an entire word of storage. The word size refers to the amount of data that is processed as a single unit for error detection and correction purposes in ECC memory systems. In an example where the word size is four bytes, a host that wants to write only a single byte of data to the word must read the entire 4-byte word, check and correct the data, substitute the new byte, recalculate the new ECC value on the entire 4-byte word, and then write all four bytes to memory with the appropriate new ECC data. This procedure is called a partial write or a read-modify-write. A partial write is any write that is for any number of bits/bytes that is less than the whole data word in the memory.

Every partial write uses at least two memory accesses with the ECC check bits recalculated in between these accesses. Typically, these memory accesses cannot be performed back-to-back because of the ECC recalculation and memory latency. For example, it may take at least three clock cycles to perform the partial write, assuming that the memory device includes a full hardware ECC calculation circuit. If the ECC is recalculated in firmware, this implementation can add several additional clock cycles. This represents a significant latency penalty for partial writes.

Disclosed in some examples are methods, memory devices, and machine-readable mediums that reduce a partial write latency to error detection and/or correcting memory systems. In some examples, the disclosed techniques use either two port, or pseudo two-port memory and an ECC cache to minimize partial-write latency to a single clock cycle. In some examples, on a first clock cycle, the CPU puts partial write data on the bus along with the write address (but does not include an updated ECC). At the same time, the memory device outputs the previous value stored at that address and the previous ECC. At the next clock cycle, the new (updated) ECC is calculated and stored in an ECC cache. During a same clock cycle as the new ECC is being calculated and stored, the previous data integrity can be checked and another write, either partial or full, can occur. Thus, the CPU is not stalled waiting for previous partial write to conclude.

A series of writes can continue back-to-back so long as the ECC cache is able to store additional ECC data. At various times, when one or more conditions are met (e.g., the ECC cache is full, the system is idle, or the like), the ECC cache can start writing the updated ECC back to the memory. Writing only the ECC to the memory can be done similarly to the partial data write, utilizing bit/byte write enables. Thus, assuming the ECC cache has a depth of N, the proposed system allows at least N non-stop partial write bursts without the extra latency traditionally involved in these partial writes. Furthermore, if multiple partial writes issued to the same address, the system can accommodate more than N partial writes as it will update the ECC stored in an already existing cache entry (e.g., it will not need an additional cache entry to store the latest updated ECC). This can help reduce writes to the ECC portion of the memory where many accesses are made to same memory addresses, which may be common for some byte processing algorithms.

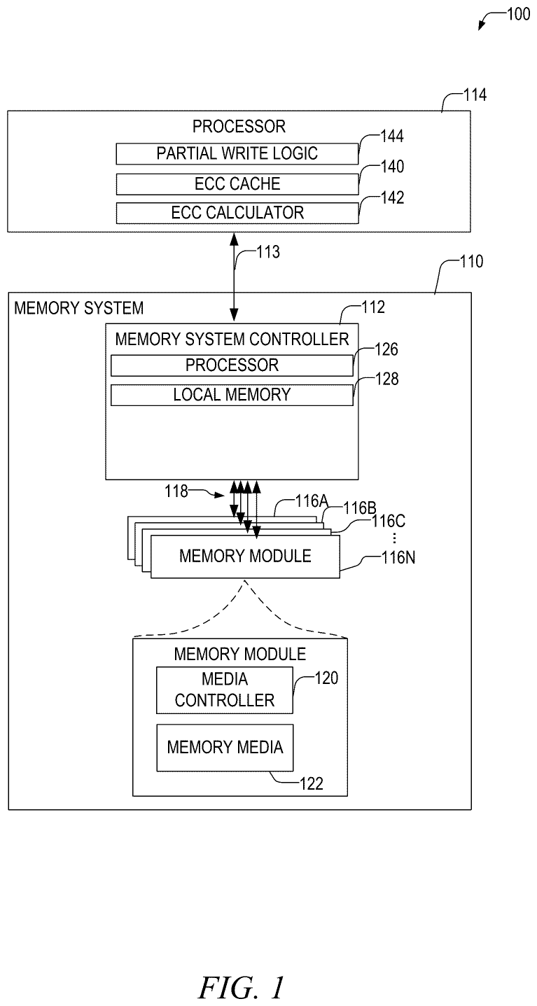

FIG. 1 illustrates an example computing environment 100 including a memory system 110, in accordance with some examples of the present disclosure. In some examples the memory system 110 can be volatile storage such as Random Access Memory (RAM), cache memory, dynamic RAM (DRAM), synchronous DRAM (SDRAM), double data rate SDRAM (DDR), static RAM (SRAM), Graphics DDR (GDDR), or the like. In some examples, the memory system 110 can be non-volatile storage such as a Not-AND (NAND) flash, NOR flash, magnetic storage (e.g., a hard-disk drive), tape storage, or the like. In some examples, the memory system 110 can include both volatile and non-volatile storage, by utilizing, for example, memory modules 116A-N containing different types of memory media 122 or by utilizing one or more single memory modules that include both volatile and non-volatile memory media 122. The memory system 110 may be an error-correcting memory system in that at least some of the memory media 122 includes error correcting memory.

In an example, the memory system 110 can be a discrete memory and/or storage device component of a host system. In other examples, the memory system 110 can be a portion of an integrated circuit (e.g., system on a chip (SOC), etc.), stacked or otherwise included with one or more other components of a host system. In some examples, the memory system 110 may be part of a distributed memory system with multiple memory systems 110 and multiple host systems that may each include one or more processors 114. For example, a distributed memory system may operate according to a Compute Express Link (CXL) framework, such as a CXL.mem framework. The memory system may also have compute capabilities to support compute-near-memory functionalities-e.g., by using the processor 126 of memory system controller 112, media controller 120, or some other processor that is not shown.

As noted, the processor 114, as well as memory system 110 can be integrated into a single host computing system. The host system can be in the form of a desktop computer, laptop computer, network server, mobile device, or such computing device that includes a memory and a processing device. The host system and/or the memory system 110 can be included in a variety of products, such as IoT devices (e.g., a refrigerator or other appliance, sensor, motor or actuator, mobile communication device, automobile, drone, etc.) to support processing, communications, or control of the product. The host system can include or be coupled to the processor 114 and to the memory system 110 so that the host system can read data from or write data to the memory system 110. As used herein, “coupled to” generally refers to a connection between components, which can be an indirect communicative connection or direct communicative connection (e.g., without intervening components), whether wired or wireless, including connections such as, electrical, optical, magnetic, and the like.

The memory system 110 is configured with a memory system controller 112 that interfaces with the processor 114. This processor, which may be a multi-core hardware processor, communicates with the memory system controller 112 via a memory controller interface 113. Through this interface, the processor 114 can issue commands to the memory system controller 112, such as a request to store data, which is accompanied by the data itself and potentially the target memory address for storage. In response, the memory system controller 112 can acknowledge the command and execute the data storage operation, providing confirmation back to the processor 114 through the memory controller interface 113. Similarly, the processor 114 is capable of sending a command to retrieve data, specifying the memory address from which to load the data. Upon receiving such a command, the memory system controller 112 retrieves the requested data and delivers it to the processor 114 through the memory controller interface 113.

In certain embodiments, the processor 114 and the memory system controller 112 are integrated onto a single die or different dies, but within a unified package. For example, in systems based on the x86 architecture, the memory system controller 112 is typically on the same die as the processor cores of processor 114, thereby streamlining the memory access operations. Alternatively, there are configurations where the memory system controller 112 is situated on a distinct die, separate from that of the processor 114 but within a same CPU package, allowing for modular design and potential customization of the memory system. In yet other examples, the memory system controller 112 may not be on the same die or package as the processor 114.

The processor 114 may communicate with the memory system controller 112 through a memory controller interface 113 and the memory system controller 112 may communicate with one or more memory modules 116A-116N upon which the physical memory is located through the memory module interface 118. In examples in which the memory system controller 112 is not on the same die or package as the processor 114, the memory controller interface 113 may be the system bus, front-side bus, or other interface and the memory module interface 118 may be an internal bus of the memory system 110, such as internal pins or traces or some other interface. In other examples, where the memory system controller 112 is on a same die or package as the processor 114, the memory controller interface 113 may be one or more traces, pins, or some other interface and the memory module interface 118 may be a system bus.

The memory controller interface 113 and/or the memory module interface 118 may, depending on the design of the system, operate as one or more traces or pins, a Peripheral Component Interconnect-Express (PCIe) interface, a UFS interface, a serial advanced technology attachment (SATA) interface, a universal serial bus (USB) interface, a Fibre Channel interface, Serial Attached SCSI (SAS) interface, memory fabric, an eMMC interface, or the like.

The memory modules, designated as 116A through 116N, are capable of incorporating a diverse array of memory media 122, which may be either volatile or non-volatile in nature. The memory media 122 is comprised of elements such as memory cells, magnetic sectors, or equivalent data storage units. These memory modules can manifest in various configurations, including but not limited to Single Inline Memory Modules (SIMMs), Dual Inline Memory Modules (DIMMs), Solid State Drives (SSDs), embedded MultiMediaCards (eMMCs), Hard Disk Drives (HDDs), tape drives, among others. The memory media 122 within modules 116A-116N may encompass Random Access Memory (RAM), Static RAM (SRAM), Dynamic RAM (DRAM), Synchronous DRAM (SDRAM), NAND flash memory, magnetic media, phase-change memory (PCM), magneto-resistive random access memory (MRAM), NOR flash memory, electrically erasable programmable read-only memory (EEPROM), cross-point memory, and similar technologies. For instances where the memory media 122 consists of NAND-type memory, the configuration may involve a range of cell architectures, from single-level cells (SLCs) to multi-level cells (MLCs). MLCs may include triple-level cells (TLCs), quad-level cells (QLCs), and the like.

In some examples, the data storage units of the memory media 122 (such as memory cells) may be organized into one or more logical structures. For volatile storage, one example of a logical organization groups memory cells by ranks, banks, rows, and columns. For non-volatile storage, one example logical organization includes grouping cells into planes, sub-blocks, blocks, and/or pages. Other logical organizations may include sectors, tracks, cylinders, clusters, and so on.

In some examples, one or more of the memory modules 116A-116N may include a media controller 120 that may handle tasks such as accessing data from the memory media, writing data to the memory media, refreshing memory cells and communications over the memory module interface with the memory system controller 112. For example, the media controller 120 can parse a command and determine the affected memory cells from the memory media 122 and can read and/or write a desired value to those memory cells. Media controller 120 can be responsible for refreshing or otherwise maintaining the data stored in the memory media 122. In some examples, the media controller 120 may handle one or more of the functions traditionally associated with the memory system controller 112. In some examples, the memory modules 116A-N do not include a media controller 120.

The media controller 120 can include hardware such as one or more integrated circuits and/or discrete components, a buffer memory, or a combination thereof. The media controller 120 can be a microcontroller, special purpose logic circuitry (e.g., a field programmable gate array (FPGA), an application specific integrated circuit (ASIC), etc.), or other suitable processor(s). The media controller 120 can include a processor (processing device) configured to execute instructions stored in a local memory. Media controller 120 can also include address circuitry, row decoders, I/O circuitry write circuitry, column decoders, sensing circuitry, and other latches for decoding addresses, writing to, and reading from the memory media 122.

The local memory of the media controller 120 can include embedded memory configured to store instructions for performing various processes, operations, logic flows, and routines that control the memory media 122, including handling communications between the memory module 116A-116N and the memory system controller 112. In some embodiments, the local memory of the media controller 120 can include memory registers storing, e.g., memory pointers, fetched data, etc. The local memory can also include read-only memory (ROM) for storing micro-code.

The memory system controller 112 can include a processor 126 configured to execute instructions stored in a local memory 128. The processor 126 can be a microcontroller, special purpose logic circuitry (e.g., a field programmable gate array (FPGA), an application specific integrated circuit (ASIC), etc.), general purpose processor configured by software (e.g., firmware), or other suitable processor. In the illustrated example, the local memory 128 may store instructions for performing various processes, operations, logic flows, and routines that control operation of the memory system 110, including handling communications between the memory system 110 and the processor 114 and communications between the memory system controller 112 and the memory modules 116A-116N. In some embodiments, the local memory 128 of the memory system controller 112 can include memory registers storing, e.g., memory pointers, fetched data, etc. The local memory can also include read-only memory (ROM) for storing micro-code.

Local memory 128 may also include various management tables such as translation tables translating logical addresses used by the processor 114 into physical memory addresses that define a physical location of the memory cells. In other examples, the management tables can instead or additionally include information regarding block age, block erase count, error history, or one or more error counts (e.g., a write operation error count, a read bit error count, a read operation error count, an erase error count, etc.) for one or more blocks of memory cells coupled to the memory system controller 112.

As noted, the memory system controller 112 can receive commands or operations from the processor 114 (or other component of a host) and can convert the commands or operations into instructions or appropriate commands to achieve the desired access to the memory modules 116A to 116N. The memory system controller 112 can be responsible for other operations such as wear leveling operations (e.g., garbage collection operations, reclamation), error detection and error-correcting code (ECC) operations, refresh operations, encryption operations, caching operations, block retirement, and address translations between a logical block address and a physical block address that are associated with the memory modules 116A to 116N. The memory system controller 112 can further include interface circuitry to communicate with the processor via the memory controller interface 113. The interface circuitry can convert the commands received from the processor 114 into command instructions to access the memory modules 116A to 116N over the memory module interface 118 as well as convert responses associated with the memory modules 116A to 116N into information for the processor 114 or other component of the host system.

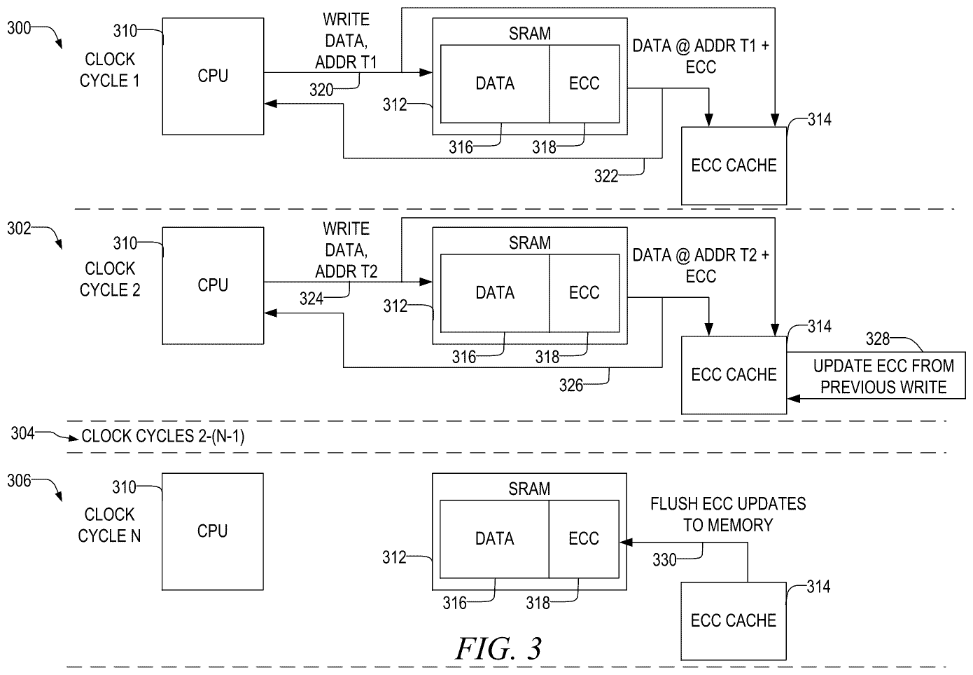

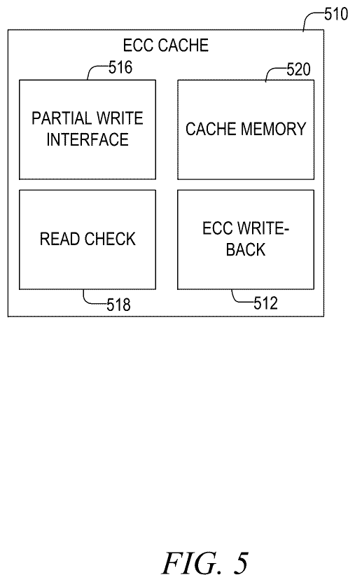

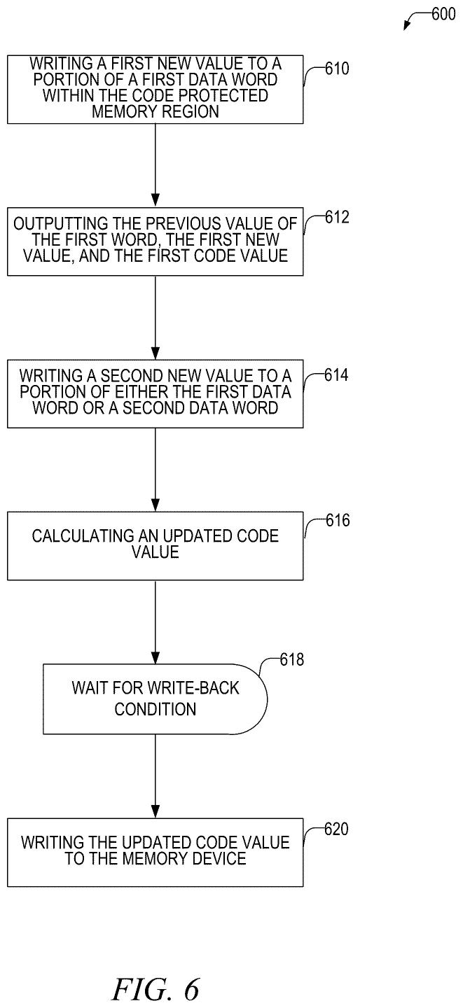

Processor 114 may include an ECC cache 140 for storing ECC values. Processor 114 may include an ECC calculator 142 for calculating and checking ECC values. In other examples, processor 114 may recalculate the ECC using software rather than having dedicated hardware in ECC calculator 142. Processor 114 may include a partial write logic 144 that performs the processing shown in FIGS. 3 and/or 4 and/or one, a plurality of, or all of the operations of FIG. 6 (e.g., those operations of FIG. 6 that are performed by the processor depending on the implementation). In other examples, the memory system 110, such as the memory system controller 112 may include the ECC cache 140 and/or ECC calculator 142. The ECC cache is described in greater detail in FIG. 5.

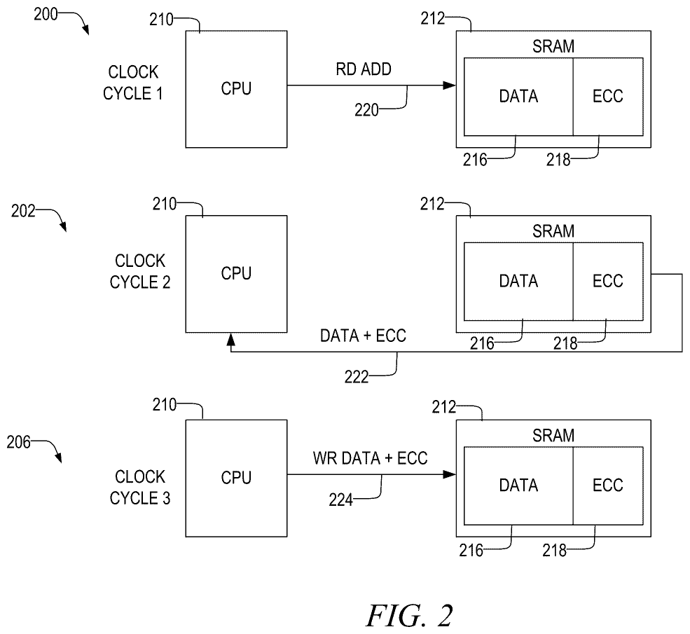

FIG. 2 illustrates a partial write according to some examples of the present disclosure. CPU 210 may be an example of processor 114 of FIG. 1 and SRAM 212 may be an example of memory system 110. During the first Clock Cycle 200 the CPU 210 initiates a read operation by accessing the SRAM 212 to read data by issuing a read command 220 with a read address. During this clock cycle, the CPU is active in sending the read command, but the SRAM does not yet provide the requested data. The DATA portion 216 and ECC portion 218 within the SRAM process the read operation and during the second Clock Cycle 202, in response to the read operation initiated in the first Clock Cycle 200, the SRAM 212 sets the read data and corresponding ECC on the bus as response data 222. The example of FIG. 2 assumes a single clock cycle memory read latency. Concurrently during the second Clock Cycle 202, the CPU 210 may recalculate the new ECC with the partially updated data. It is assumed that the ECC recalculation can be done in the same clock cycle as the memory read access, which is achievable by a full hardware implementation. A software (e.g., a firmware) implementation may be used, however, such implementation may incur additional latency.

At the third Clock Cycle 206, the CPU 210 performs a write operation by sending Write Data and ECC data 224 to the SRAM 212. This write operation includes the new data and the newly recalculated ECC for the DATA portion 216 and ECC portion 218, respectively. This concludes the read-modify-write sequence required for a partial write to an ECC protected area.

In this diagram, if another partial access is required immediately after, the process would repeat starting from the first Clock Cycle 200, resulting in at least three clock cycles per required write access. Back-to-back partial writes are typically seen for byte processing and can lead to inefficiencies, particularly when multiple partial writes are needed, as the whole procedure can take a significant number of clock cycles, increasing latency and reducing overall performance.

FIG. 3 illustrates an improved partial write according to some examples of the present disclosure. CPU 310 may be an example of processor 114 of FIG. 1 and SRAM 312 may be an example of memory system 110. The memory device used in FIG. 3 is a pseudo two-port memory or a two-port memory (such as SRAM) according to some examples of the present disclosure. At the first Clock Cycle 300, the CPU 310 initiates a partial write operation with data to address T1 320. Concurrently during this clock cycle, the SRAM 312 provides the previous data at address T1 and the associated ECC data 322 on the bus. In some examples, this data may be stored in an ECC cache 314, another cache, registers, memory, or the like. In some examples, this data is processed on the next clock cycle and may not need to be stored. This simultaneous action allows the CPU to perform a partial write without waiting for a separate read cycle to complete. At the second Clock Cycle 302, which may immediately follow the first Clock Cycle 300, the CPU 310 may perform a different partial write operation with data to address T2 324. T1 and T2 may be a same address or a different address. Simultaneously, the SRAM 312 supplies the previous data at address T2 and the associated ECC data 326 on the bus. At the same time during the second Clock Cycle 302, the ECC cache 314 and/or the CPU 310 calculates and stores the new updated ECC for the data written to T1 during the first Clock Cycle 300 at operation 328 using the previous data at address T1 and the associated ECC data 322. The new ECC may be stored in association with the address at T1. First, Second, and successive clock cycles through Clock Cycle (N-1) 304 represent a series of continuous partial write operations similar to the first and second Clock Cycles. The CPU 310 can perform back-to-back partial writes to any address (including the address written to in the first or second Clock Cycles) without stalling. The SRAM 312 provides the previous data and ECC for each corresponding address, while the ECC cache 314 updates the ECC values for each partial write.

At the n-th Clock Cycle 306 after the burst of one or more partial writes has concluded and the memory bus is inactive (e.g., the CPU 310 is not issuing new read or write commands), the ECC cache 314 begins writing the updated ECC values back to the ECC portion 318 of the SRAM 312 at operation 330. This process may occur during a clock cycle when the CPU 310 is not accessing the memory, allowing the ECC cache to write the updated ECC values without interfering with ongoing CPU operations.

The described solution allows for a non-stop burst of partial write operations to multiple addresses, with no extra latency involved in these writes. The ECC cache 314 enables the system to store ECC information associated with written addresses and write back only the ECC information that is associated with updated addresses, thereby reducing the total number of ECC writes and improving system performance. In addition to allowing non-stop burst of partial write operations, these partial writes may be mixed with full word writes. In some examples, a full word write may also use the ECC cache. In other examples, the full word write may skip the ECC cache and write directly to the memory. The partial and/or full word writes may be mixed with reads. In these examples, the ECC may be written back to the memory. This may be accomplished using a true 2 port ram and for pseudo-2 port ram it may or may not be possible, depending on any specific read/write access limitations of the memory.

In some examples, as used herein, the clock cycles shown in FIG. 3 are successive. That is, the second Clock Cycle 302 is immediately after the first Clock Cycle 300. In other examples, such as when a memory device needs more than one clock cycle to access, the Clock Cycles of FIG. 3 may represent memory access opportunities. That is, first Clock Cycle 300 is a first memory access opportunity; second Clock Cycle 302 is a second memory access opportunity, and so on. That is, the second Clock Cycle 302 is a second clock cycle that presents a next access opportunity to the memory device immediately subsequent to a first memory access opportunity of the first Clock Cycle 300. Thus, the Clock Cycle 300 and Clock Cycle 302 may not be sequential but may be separated by several physical clock cycles.

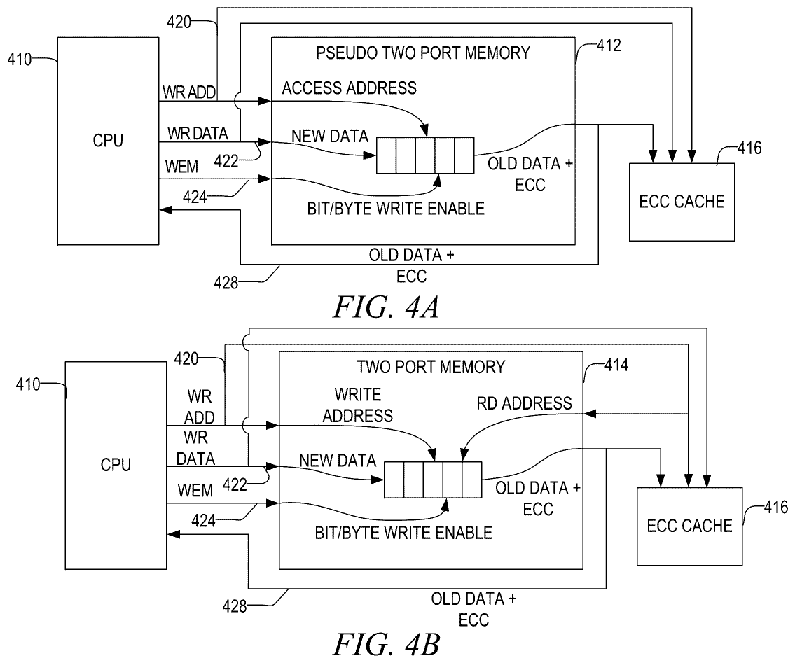

FIG. 4A illustrates a system for performing memory operations using a pseudo two-port memory 412 in conjunction with an ECC cache 416 according to some examples of the present disclosure. CPU 410 may be an example of processor 114 of FIG. 1 and pseudo two-port memory 412 may be an example of memory system 110. Pseudo two-port memory 412 may, in some examples, be static random-access memory (SRAM), dynamic random-access memory (DRAM), or the like. The CPU 410 interfaces with the pseudo two-port memory 412 to execute memory write operations such as read, writes, and partial writes. The pseudo two-port memory 412 in some examples is a memory device that is designed to mimic the behavior of a two-port memory device using internal mechanisms. It allows for the simultaneous processing of write operations and the retrieval of old data from the same memory address. The ECC cache 416 temporarily stores updated ECC values corresponding to partial writes of the CPU 410. It ensures data integrity while also allowing ECC updates to be deferred until the optimal time, reducing the overhead of immediate ECC recalculations.

The write address lines 420 carry the memory address from the CPU 410 to the pseudo two-port memory 412 where the write operation is to be performed. Additionally, the write address lines are connected to the ECC cache 416 where it is used, along with the write data lines 422 and the old ECC, to update and cache the ECC value for a partial write. For example, the ECC cache may index the updated ECC by the address for easy retrieval (e.g., upon a read operation). The write data lines 422 transmit data from the CPU 410 to be written into the memory location specified by the write address lines 420 in the pseudo two-port memory 412. The write data lines 422 are also connected to the ECC cache 416. WEM lines 424 are the write enable mask (WEM) lines that are used to control which bits of the data word are to be written or modified during a partial write operation. It allows for selective writing, enabling the CPU 410 to update only specific bits or bytes within a memory word. As the CPU 410 performs a write operation, the pseudo two-port memory 412 concurrently provides the old data and associated ECC 428 from the targeted memory address. This data is used by the ECC cache 416 to update the ECC values corresponding to the newly written data.

In operation, the CPU 410 sends a write command along with the target address and data via the write address lines 420 and write data lines 422, respectively. The WEM lines 424 specifies which parts of the data word are to be updated. Simultaneously, the pseudo two-port memory 412 outputs the old data and ECC 428 for the same address, which is then used by the ECC cache 416 to calculate the updated ECC. This system allows for efficient write operations with concurrent ECC management, improving overall memory system performance.

FIG. 4B illustrates a system for performing memory operations using a two-port memory 414 in conjunction with an ECC cache 416 according to some examples of the present disclosure. CPU 410 may be an example of processor 114 of FIG. 1 and two-port memory 414 may be an example of memory system 110. In the two-port memory 414 implementation, the implementation differs from FIG. 4A in that the write address lines 420 are copied onto the read address input lines of the two port SRAM. Since the read and write operations are completely decoupled from each other in the two-port SRAM, the ECC cache 416 can write updated ECC back during ongoing read operations from the CPU 410.

In addition to pseudo two-port and two-port memory, other multi-port memories may be utilized that may increase efficiency even more. These multi-port memories may, however, increase efficiency at the expense of larger area and power.

FIG. 5 illustrates a logical diagram of an ECC cache system designed to optimize memory operations by efficiently managing error-correcting codes during partial write operations according to some examples of the present disclosure. The ECC cache 510 depicted may serve as a more detailed example of the ECC cache 140 shown in FIG. 1 of the disclosure. The ECC cache 510 may be part of the processor of the host system, such as processor 114, part of the memory controller, such as memory system controller 112, media controller 120, or a separate component communicatively coupled to the processor 114, or memory system 110. In still other examples, one or more of the components of ECC cache 510 may be performed by any of the processors of the host system, such as processor 114, memory system controller 112, media controller 120, and/or a separate component.

ECC cache 510 interfaces with the CPU to facilitate the recalculation and temporary storage of ECC values corresponding to newly written data in memory. ECC cache 510 includes a partial write interface 516 that receives write address inputs, write data, previous data, and previous ECC data. Upon receipt of these items, the partial write interface 516 may utilize the ECC calculator of the processor (e.g., ECC calculator 142 of processor 114 of FIG. 1, a separate circuit, or the like) to recalculate the ECC based on the new data written and the previous data and ECC values. The ECC cache 510 may include cache memory 520 which is responsible for storing the updated ECC information along with the addresses of that information in cache records. It maintains a record of all addresses that have undergone partial writes and the corresponding updated ECC values. The read check component 518 determines whether a read request by the processor for a particular address is targeting a memory location that has an updated ECC stored in the cache. If so, it provides the updated ECC value to ensure data integrity during the read operation. The ECC write back component 512 is responsible for managing the write-back of updated ECC values to the memory device based upon one or more policies that determine the optimal timing. The ECC write back component 512 may employ various strategies, such as delayed write-back, write-back on cache eviction, or write-back based on a threshold or timeout condition, to enhance performance and reduce unnecessary memory accesses. In some examples, operations 610 and 612 may be performed during a first clock cycle and operations 614 and 616 may be performed during a second clock cycle that presents a next access opportunity to the memory device immediately subsequent to a first memory access opportunity of the first clock cycle. In examples in which the memory device is able to be accessed every clock cycle, the second clock cycle may be a clock cycle immediately after the first clock cycle. In examples in which the memory device takes three clock cycles to access, operations 614 and 616 may be performed at the next access opportunity—i.e., three clock cycles after the first clock cycle.

In operation, when the CPU executes a partial write, the partial write interface 516 captures the necessary data and utilizes the ECC calculator to compute the new ECC (as noted the ECC calculator may be on the CPU or may be a separate circuit). The updated ECC is then stored in the cache memory 520 along with the address of the write operation. The read check component 518 ensures that any subsequent read operations that access the same addresses are supplied with the correct ECC from the cache. Finally, the ECC write back component 512 determines the appropriate time to write the updated ECC values back to the memory, based on the selected write-back policy, thereby optimizing memory performance and power efficiency. Upon a write-back of the ECC cache values to the memory, the ECC cache records may be evicted (removed) from the cache to make room for new records.

Various cache write-back policies may be utilized depending on the desired optimization goals. A first example cache write-back policy waits until the ECC memory is idle. While this policy is simple, it may not be ideal for data access patterns that may have short pauses between accesses. The CPU may then restart partial writes to the memory before the ECC cache has finished writing back the ECC values. The ECC cache may then either continue to write-back the ECC values, which can lead to reduced performance, or may pause writing back the ECC values until the memory is idle again.

In some examples, a write-back policy may employ a timer. This policy delays the write-back of updated ECC values to the memory until after a specified timeout period has elapsed after the memory becomes idle. The rationale behind this approach is to account for the possibility that the CPU may continue to perform write operations to the same memory addresses within a short time frame. By delaying the ECC write-back, the system avoids unnecessary write operations that would otherwise occur if the ECC were updated prematurely. Under this policy, only when the data processing is done and the timeout expires will the cache write the ECC back to the memory. This can save significant power by eliminating intermediate ECC evictions. The timeout can be advantageous if the CPU performs cyclic operations with some wait states between memory accesses.

In still other examples, the system may utilize a threshold condition. For example, if the cache exceeds a threshold level of utilization (e.g., the number of cache entries is above a threshold number of cache entries), then the system may write back the cache entries to the ECC memory. In some examples, the system may define a threshold window with an upper and lower threshold. Write-back is triggered when the utilization of the cache exceeds an upper threshold and continues until the cache utilization reaches the lower threshold.

Another example policy may be an age-based write-back that triggers a write-back once the ECC value for a particular address has been in the cache for a predetermined amount of time. This age threshold ensures that ECC values are not kept in the cache indefinitely. The write-back may be scheduled immediately, for idle periods, or the like.

In other examples, the system may utilize adaptive learning algorithms that learn from the system's memory access patterns to predict optimal times for ECC write-back. It adjusts its predictions over time to improve accuracy. For example, such algorithms can use pattern matching mechanisms that collect information about periods of system activity and inactivity to discern usage patterns. For example, timestamped logs of memory access events and/or CPU activity can be used. The logs may be used to identify patterns using simple metrics, such as an average or mean time between low activity periods. This may be used to set the thresholds and the timeout values for other timing policies.

Each of these algorithms can be implemented individually or in combination to create a robust system for managing ECC write-backs. The choice of policy algorithm(s) may depend on the specific design goals, such as minimizing latency, maximizing throughput, reducing power consumption, or maintaining data integrity.

FIG. 6 illustrates a flowchart depicting an exemplary method 600 for performing a partial write to a code-protected memory region of a memory device, according to some examples of the present disclosure. At operation 610, during a first clock cycle, the method commences with writing a first value to a portion of a first data word within the code-protected memory region. The first data word is protected by a first code value, such as an Error-Correcting Code (ECC), and the portion to which the new value is written is smaller than the entirety of the first data word.

Following the partial write at operation 610, at operation 612 and still during the first clock cycle, the error protected memory region outputs the previous value of the first word and the first code value associated with the first word. This output facilitates the subsequent calculation of an updated code value and to preserve the integrity of the data during the partial write process.

At operation 614, during a next clock cycle (e.g., immediately subsequent the first clock cycle) the method proceeds to write a second new value to a portion of either the same first data word or a second data word within the code-protected memory region. This operation allows for continuous data processing and updating without the need for a full read-modify-write cycle for each partial write. At operation 616, such as during the same clock cycle as operation 614, the system calculates an updated code value. This calculation uses the previous value of the first word, the first new value of the first partial word, and the first code value that was protecting the first word. The updated code value ensures that the integrity of the data is maintained after the partial writes.

At operation 618, the system continues processing additional data writes or other operations until a write-back condition is detected. The write-back condition is a predefined criterion that determines the optimal timing for writing the updated code value back to the memory device. This condition could be based on a variety of factors, including but not limited to cache occupancy levels, system activity, or elapsed time.

Finally, at operation 620, once the write-back condition is met, the system writes the updated code value back to the memory device. This write-back operation updates the code-protected memory region with the new ECC or other code values, thereby ensuring the data integrity is preserved following the partial writes.

While the examples described herein primarily focused on ECC based RAM, it will be appreciated by a person of ordinary skill in the art with the benefit of the present disclosure, that the methods and devices described herein are applicable and adaptable to any memory device or memory-like device utilizing code words to protect the memory where a partial-write is desired. In addition, while the examples described herein primarily focused on error-correcting memory systems, it will be appreciated by a person of ordinary skill in the art with the benefit of the present disclosure that the techniques described are also applicable to error-detection memory systems. As noted, the above techniques may be utilized with ECC memory, but in other examples, the techniques described herein may be utilized with other types of error-correcting memory systems including Forward Error Correction (FEC), low density codes, high density codes, parity codes, cyclic redundancy checks, and the like.

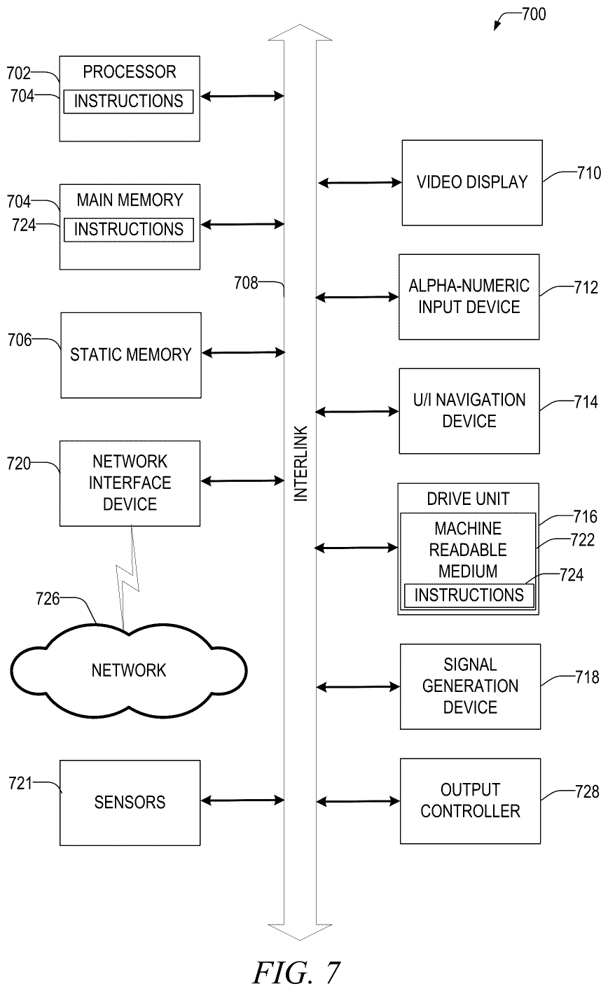

FIG. 7 illustrates a block diagram of an example machine 700 within or upon which any one or more of the techniques (e.g., methodologies) discussed herein may be performed. In alternative embodiments, the machine 700 may operate as a standalone device or may be connected (e.g., networked) to other machines. In a networked deployment, the machine 700 may operate in the capacity of a server machine, a client machine, or both in server-client network environments. In an example, the machine 700 may act as a peer machine in the peer-to-peer (P2P) (or other distributed) network environment. The machine 700 may be in the form of a personal computer (PC), a tablet PC, a set-top box (STB), a personal digital assistant (PDA), a mobile telephone, a smart phone, a web appliance, a network router, switch or bridge, a distributed computing architecture, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. Machine 700 may be or include components shown in FIGS. 1-5 and be configured to perform the methods of FIG. 6. The components shown in FIG. 7 are exemplary and actual implementations may include more or fewer such components.

Examples, as described herein, may include, or may operate on one or more logic units, components, or mechanisms (hereinafter “components”). Components are tangible entities (e.g., hardware) capable of performing specified operations and may be configured or arranged in a certain manner. In an example, circuits may be arranged (e.g., internally or with respect to external entities such as other circuits) in a specified manner as a component. In an example, the whole or part of one or more computer systems (e.g., a standalone, client or server computer system) or one or more hardware processors may be configured by firmware or software (e.g., instructions, an application portion, or an application) as a component that operates to perform specified operations. In an example, the software may reside on a machine readable medium. In an example, the software, when executed by the underlying hardware of the component, causes the hardware to perform the specified operations of the component.

Accordingly, the term “component” is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which components are temporarily configured, each of the components need not be instantiated at any one moment in time. For example, where the components comprise a general-purpose hardware processor configured using software, the general-purpose hardware processor may be configured as respective different components at different times. Software may accordingly configure a hardware processor, for example, to constitute a particular module at one instance of time and to constitute a different component at a different instance of time.

Machine (e.g., computer system) 700 may include one or more hardware processors, such as processor 702. Processor 702 may be a central processing unit (CPU), a graphics processing unit (GPU), a hardware processor core, or any combination thereof. Machine 700 may include a main memory 704 and a static memory 706, some or all of which may communicate with each other via an interlink (e.g., bus) 708. Examples of main memory 704 may include Synchronous Dynamic Random-Access Memory (SDRAM), such as Double Data Rate memory, such as DDR4 or DDR5. Interlink 708 may be one or more different types of interlinks such that one or more components may be connected using a first type of interlink and one or more components may be connected using a second type of interlink. Example interlinks may include a memory bus, a peripheral component interconnect (PCI), a peripheral component interconnect express (PCIe) bus, a universal serial bus (USB), or the like.

The machine 700 may further include a display unit 710, an alphanumeric input device 712 (e.g., a keyboard), and a user interface (UI) navigation device 714 (e.g., a mouse). In an example, the display unit 710, input device 712 and UI navigation device 714 may be a touch screen display. The machine 700 may additionally include a storage device (e.g., drive unit) 716, a signal generation device 718 (e.g., a speaker), a network interface device 720, and one or more sensors 721, such as a global positioning system (GPS) sensor, compass, accelerometer, or other sensor. The machine 700 may include an output controller 728, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 716 may include a machine readable medium 722 on which is stored one or more sets of data structures or instructions 724 (e.g., software) embodying or utilized by any one or more of the techniques or functions described herein. The instructions 724 may also reside, completely or at least partially, within the main memory 704, within static memory 706, or within the hardware processor 702 during execution thereof by the machine 700. In an example, one or any combination of the hardware processor 702, the main memory 704, the static memory 706, or the storage device 716 may constitute machine readable media.

While the machine readable medium 722 is illustrated as a single medium, the term “machine readable medium” may include a single medium or multiple media (e.g., a centralized or distributed database, and/or associated caches and servers) configured to store the one or more instructions 724.

The term “machine readable medium” may include any medium that is capable of storing, encoding, or carrying instructions for execution by the machine 700 and that cause the machine 700 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); Solid State Drives (SSD); and CD-ROM and DVD-ROM disks. In some examples, machine readable media may include non-transitory machine readable media. In some examples, machine readable media may include machine readable media that is not a transitory propagating signal.

The instructions 724 may further be transmitted or received over a communications network 726 using a transmission medium via the network interface device 720. The Machine 700 may communicate with one or more other machines wired or wirelessly utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks such as an Institute of Electrical and Electronics Engineers (IEEE) 802.11 family of standards known as Wi-Fi®, an IEEE 802.15.4 family of standards, a 5G New Radio (NR) family of standards, a Long Term Evolution (LTE) family of standards, a Universal Mobile Telecommunications System (UMTS) family of standards, peer-to-peer (P2P) networks, among others. In an example, the network interface device 720 may include one or more physical jacks (e.g., Ethernet, coaxial, or phone jacks) or one or more antennas to connect to the communications network 726. In an example, the network interface device 720 may include a plurality of antennas to wirelessly communicate using at least one of single-input multiple-output (SIMO), multiple-input multiple-output (MIMO), or multiple-input single-output (MISO) techniques. In some examples, the network interface device 720 may wirelessly communicate using Multiple User MIMO techniques.

### Other Notes and Examples

Example 1 is a method for performing a partial write to an error protected memory region of a memory device, the method comprising: during a first clock cycle: writing a first value to a portion of a first data word within the error protected memory region, the first data word protected by a first code value written to the memory device, the portion of the first data word sized smaller than the first data word; and outputting, from the code protected memory region, a previous value of the first data word, and the first code value; during a second clock cycle that presents a next access opportunity to the memory device immediately subsequent to a first memory access opportunity of the first clock cycle: writing a second new value to a portion of either the first data word or a second data word within the error protected memory region; and determining a second code value using the outputted previous value of the first data word, the first new value, and the outputted first code value protecting the first data word; and storing the second code value in a cache; and at a subsequent time after the first and second clock cycle, writing the second code value to the memory device.

In Example 2, the subject matter of Example 1 includes, wherein the method further comprises, during the second clock cycle: verifying an integrity of the previous value of the first data word using the first code value.

In Example 3, the subject matter of Examples 1-2 includes, during a third clock cycle prior to writing the second code value to the memory device: receiving a read request for the first data word; and providing a value of the first data word from the memory device and providing the second code value from the cache.

In Example 4, the subject matter of Examples 1-3 includes, wherein the subsequent time after the first and second clock cycle where the second code value is written to the memory device is determined based upon an inactivity of the error protected memory region.

In Example 5, the subject matter of Example 4 includes, wherein the subsequent time after the first and second clock cycle where the second code value is written to the memory device is determined based upon an expiry of a predefined time period after an inactivity of the error protected memory region is detected.

In Example 6, the subject matter of Examples 1-5 includes, wherein the subsequent time after the first and second clock cycle where the second code value is written to the memory device is determined based upon the cache reaching a prespecified occupancy threshold.

In Example 7, the subject matter of Examples 1-6 includes, wherein the memory device is a two-port, pseudo two-port memory device, or multi-port memory device.

Example 8 is a memory system for performing a partial write to an error protected memory region of a memory, the system comprising a hardware processor configured to perform the operations comprising: during a first clock cycle: writing a first value to a portion of a first data word within the error protected memory region, the first data word protected by a first code value written to the memory device, the portion of the first data word sized smaller than the first data word; and outputting, from the code protected memory region, a previous value of the first data word, and the first code value; during a second clock cycle that presents a next access opportunity to the memory device immediately subsequent to a first memory access opportunity of the first clock cycle: writing a second new value to a portion of either the first data word or a second data word within the error protected memory region; and determining a second code value using the outputted previous value of the first data word, the first new value, and the outputted first code value protecting the first data word; and storing the second code value in a cache; and at a subsequent time after the first and second clock cycle, writing the second code value to the memory device.

In Example 9, the subject matter of Example 8 includes, wherein the operations further comprise, during the second clock cycle: verifying an integrity of the previous value of the first data word using the first code value.

In Example 10, the subject matter of Examples 8-9 includes, wherein the operations further comprise: during a third clock cycle prior to writing the second code value to the memory device: receiving a read request for the first data word; and providing a value of the first data word from the memory device and providing the second code value from the cache.

In Example 11, the subject matter of Examples 8-10 includes, wherein the subsequent time after the first and second clock cycle where the second code value is written to the memory device is determined based upon an inactivity of the error protected memory region.

In Example 12, the subject matter of Example 11 includes, wherein the subsequent time after the first and second clock cycle where the second code value is written to the memory device is determined based upon an expiry of a predefined time period after an inactivity of the error protected memory region is detected.

In Example 13, the subject matter of Examples 11-12 includes, wherein the subsequent time after the first and second clock cycle where the second code value is written to the memory device is determined based upon the cache reaching a prespecified occupancy threshold.

In Example 14, the subject matter of Examples 8-13 includes, wherein the memory device is a two-port, pseudo two-port memory device, or multi-port memory device.

Example 15 is a memory system, the memory system comprising: a hardware processing unit configured to execute memory write operations; a memory communicatively coupled to the hardware processing unit and configured to store data and associated error-correcting code (ECC) values, wherein the memory comprises: a write address input to receive a memory address for a write operation from the hardware processor; a write data input to receive data for the write operation from the hardware processor; a write enable mask (WEM) input to receive control signals from the hardware processor indicating which bits of a data word are to be written or modified during the write operation; and an output to provide previous data and associated ECC from a targeted memory address concurrent with receiving the write operation from the hardware processor; and an ECC cache communicatively coupled to the hardware processor and the memory, the ECC cache configured to: temporarily store updated ECC values corresponding to partial writes executed by the hardware processor; utilize the previous data and associated ECC provided by the memory to calculate the updated ECC values; and manage write-back of the updated ECC values to the memory based on a predefined criterion.

In Example 16, the subject matter of Example 15 includes, wherein the memory device is a pseudo two-port memory device.

In Example 17, the subject matter of Examples 15-16 includes, wherein the memory device is a two-port memory device where a read address input is coupled to the write address input from the hardware processor to allow simultaneous processing of write operations and retrieval of old data from the same memory address.

In Example 18, the subject matter of Examples 15-17 includes, wherein the ECC cache includes a plurality of cache entries, and the predefined criterion includes initiating the write-back when the number of cache entries storing updated ECC values reaches a predefined cache capacity limit.

In Example 19, the subject matter of Examples 15-18 includes, wherein the predefined criterion for the write-back of the updated ECC values is based on a timer, such that the write-back is initiated after a predetermined period of inactivity of the memory.

In Example 20, the subject matter of Examples 15-19 includes, wherein the hardware processing unit is configured to issue a series of back-to-back partial write operations to the memory, and the ECC cache is configured to update ECC values in the cache for each partial write without stalling the hardware processing unit.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

What is claimed is:

1. A method for performing a partial write to an error protected memory region of a memory device, the method comprising:
during a first clock cycle:
writing a first value to a portion of a first data word within the error protected memory region, the first data word protected by a first code value written to the memory device, the portion of the first data word sized smaller than the first data word; and
outputting, from the code protected memory region, a previous value of the first data word, and the first code value;
during a second clock cycle that presents a next access opportunity to the memory device immediately subsequent to a first memory access opportunity of the first clock cycle:
writing a second new value to a portion of either the first data word or a second data word within the error protected memory region; and
determining a second code value using the outputted previous value of the first data word, the first new value, and the outputted first code value protecting the first data word; and
storing the second code value in a cache; and
at a subsequent time after the first and second clock cycle, writing the second code value to the memory device.

2. The method of claim 1, wherein the method further comprises, during the second clock cycle:
verifying an integrity of the previous value of the first data word using the first code value.

3. The method of claim 1, further comprising:
during a third clock cycle prior to writing the second code value to the memory device:
receiving a read request for the first data word; and
providing a value of the first data word from the memory device and providing the second code value from the cache.

4. The method of claim 1, wherein the subsequent time after the first and second clock cycle where the second code value is written to the memory device is determined based upon an inactivity of the error protected memory region.

5. The method of claim 4, wherein the subsequent time after the first and second clock cycle where the second code value is written to the memory device is determined based upon an expiry of a predefined time period after an inactivity of the error protected memory region is detected.

6. The method of claim 1, wherein the subsequent time after the first and second clock cycle where the second code value is written to the memory device is determined based upon the cache reaching a prespecified occupancy threshold.

7. The method of claim 1, wherein the memory device is a two-port, pseudo two-port memory device, or multi-port memory device.

8. A memory system for performing a partial write to an error protected memory region of a memory, the system comprising a hardware processor configured to perform the operations comprising:
during a first clock cycle:
writing a first value to a portion of a first data word within the error protected memory region, the first data word protected by a first code value written to the memory device, the portion of the first data word sized smaller than the first data word; and
outputting, from the code protected memory region, a previous value of the first data word, and the first code value;
during a second clock cycle that presents a next access opportunity to the memory device immediately subsequent to a first memory access opportunity of the first clock cycle:
writing a second new value to a portion of either the first data word or a second data word within the error protected memory region; and
determining a second code value using the outputted previous value of the first data word, the first new value, and the outputted first code value protecting the first data word; and
storing the second code value in a cache; and
at a subsequent time after the first and second clock cycle, writing the second code value to the memory device.

9. The system of claim 8, wherein the operations further comprise, during the second clock cycle:
verifying an integrity of the previous value of the first data word using the first code value.

10. The system of claim 8, wherein the operations further comprise:
during a third clock cycle prior to writing the second code value to the memory device:
receiving a read request for the first data word; and
providing a value of the first data word from the memory device and providing the second code value from the cache.

11. The system of claim 8, wherein the subsequent time after the first and second clock cycle where the second code value is written to the memory device is determined based upon an inactivity of the error protected memory region.

12. The system of claim 11, wherein the subsequent time after the first and second clock cycle where the second code value is written to the memory device is determined based upon an expiry of a predefined time period after an inactivity of the error protected memory region is detected.

13. The system of claim 11, wherein the subsequent time after the first and second clock cycle where the second code value is written to the memory device is determined based upon the cache reaching a prespecified occupancy threshold.

14. The system of claim 8, wherein the memory device is a two-port, pseudo two-port memory device, or multi-port memory device.

15. A memory system, the memory system comprising:
a hardware processing unit configured to execute memory write operations;
a memory communicatively coupled to the hardware processing unit and configured to store data and associated error-correcting code (ECC) values, wherein the memory comprises:
a write address input to receive a memory address for a write operation from the hardware processor;
a write data input to receive data for the write operation from the hardware processor;
a write enable mask (WEM) input to receive control signals from the hardware processor indicating which bits of a data word are to be written or modified during the write operation; and
an output to provide previous data and associated ECC from a targeted memory address concurrent with receiving the write operation from the hardware processor; and
an ECC cache communicatively coupled to the hardware processor and the memory, the ECC cache configured to:
temporarily store updated ECC values corresponding to partial writes executed by the hardware processor;
utilize the previous data and associated ECC provided by the memory to calculate the updated ECC values; and
manage write-back of the updated ECC values to the memory based on a predefined criterion.

16. The memory system of claim 15, wherein the memory device is a pseudo two-port memory device.

17. The memory system of claim 15, wherein the memory device is a two-port memory device where a read address input is coupled to the write address input from the hardware processor to allow simultaneous processing of write operations and retrieval of old data from the same memory address.

18. The memory system of claim 15, wherein the ECC cache includes a plurality of cache entries, and the predefined criterion includes initiating the write-back when the number of cache entries storing updated ECC values reaches a predefined cache capacity limit.

19. The memory system of claim 15, wherein the predefined criterion for the write-back of the updated ECC values is based on a timer, such that the write-back is initiated after a predetermined period of inactivity of the memory.

20. The memory system of claim 15, wherein the hardware processing unit is configured to issue a series of back-to-back partial write operations to the memory, and the ECC cache is configured to update ECC values in the cache for each partial write without stalling the hardware processing unit.
